(19) United States
(12) Patent Application Publication
(10) Pub. No.: US 2026/0143931 A1
(43) Pub. Date: May 21, 2026

(54) DISPLAY SUBSTRATE, DISPLAY PANEL, AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Ying Han, Beijing (CN); Pan Xu, Beijing (CN); Guangshuang Lv, Beijing (CN); Chengyuan Luo, Beijing (CN); Xing Zhang, Beijing (CN); Donghui Zhao, Beijing (CN); Cheng Xu, Beijing (CN)

(21) Appl. No.: 18/705,887

(22) PCT Filed: May 23, 2023
(86) PCT No.: PCT/CN2023/095841

§ 371 Date: Apr. 29, 2024

(30) Foreign Application Priority Data
Nov. 28, 2022 (WO) PCT/CN2022/134711

(51) Int. Cl. H10K 59/131; G09G 3/00; G09G 3/22; H10K 59/122

(52) U.S. Cl. CPC H10K 59/131; G09G 3/22; H10K 59/122; G09G 3/003; G09G 2300/0426; G09G 2300/0842; G09G 2300/0861; G09G 2330/021

(57) ABSTRACT

Provided are a display substrate, display panel and display device. The display substrate includes: pixel circuit units provided on a base substrate, including pixel circuit groups which includes pixel circuits and separation regions light emitting devices provided on the base substrate and electrically connected to the pixel circuits and data lines and constant signal lines provided on the base substrate. The pixel circuits and the separation regions are alternately arranged. The separation regions include first and second separation regions that are alternately arranged. The data lines are located in the first separation regions, two pixel circuits adjacent in a second direction share a same data line the constant signal lines are located in the second separation regions, different constant signal lines are located in different second separation regions and the pixel circuits in the pixel circuit unit share the constant signal lines.

### CROSS REFERENCE TO RELATED APPLICATION(S)

This application is a Section 371 National Stage Application of International Application No. PCT/CN 2023/095841, filed on May 23, 2023, which claims priority under 35 U.S.C. 365(b) and 35 U.S.C. 119(a) to PCT Application No. PCT/CN 2022/134711, filed on Nov. 28, 2022, the whole disclosures of which are incorporated herein by reference in their entireties.

### TECHNICAL FIELD

The present disclosure relates to the field of display technology, and in particular, to a display substrate, a display panel, and a display device.

### BACKGROUND

Ultra high resolution display technology may improve a display effect of a display screen and may be applied to various special displays, such as 3D display.

In the 3D display, an existing display unit is divided into a plurality of views, each view displays object information from different angles, which may achieve the 3D display by matching with microlenses. The more views, the better a 3D display effect. Moreover, the more views, the higher the resolution, a line width of a signal line may be limited, thereby a resistance on the signal line may be increased so as to increase a display power consumption.

### SUMMARY

In view of the above problems, a display substrate, a display panel, and a display device are provided.

According to a first aspect of the present disclosure, a display substrate is provided, including: a base substrate; a pixel circuit unit provided on the base substrate, the pixel circuit unit includes a plurality of pixel circuit groups arranged in a first direction, and at least one pixel circuit group includes a plurality of pixel circuits and a plurality of separation regions; a plurality of light emitting devices provided on the base substrate and electrically connected to the plurality of pixel circuits, at least one pixel circuit is electrically connected to at least one light emitting device, different pixel circuits are electrically connected to different light emitting devices, the pixel circuits in a same pixel circuit group are electrically connected to light emitting devices having the same color, and the pixel circuits in different pixel circuit groups are electrically connected to light emitting devices having different colors; and a plurality of data lines and a plurality of constant signal lines provided on the base substrate and electrically connected to the plurality of pixel circuits, the plurality of data lines and the plurality of constant signal lines extend in the first direction, the plurality of pixel circuits and the plurality of separation regions in a same pixel circuit group are alternately arranged in a second direction intersecting with the first direction; the plurality of separation regions include a plurality of first separation regions and a plurality of second separation regions, and the plurality of first separation regions and the plurality of second separation region are alternately arranged in the second direction; and the plurality of data lines are located in the plurality of first separation regions, different data lines are located in different first separation regions, two pixel circuits adjacent in the second direction share a same data line, the plurality of constant signal lines are located in the plurality of second separation regions, different constant signal lines are located in different second separation regions, and the plurality of pixel circuits in the pixel circuit unit share the plurality of constant signal lines.

According to the embodiments of the present disclosure, the plurality of constant signal lines include at least one first power line and a plurality of reference signal lines, and a distance between at least one reference signal line and the first power line adjacent to the at least one reference signal line is substantially the same as a distance between two adjacent data lines.

According to the embodiments of the present disclosure, a distance between two adjacent first power lines is substantially the same as the distance between two adjacent data lines.

According to the embodiments of the present disclosure, a distance between two adjacent constant signal lines is greater than a distance between two adjacent data lines.

According to the embodiments of the present disclosure, the plurality of constant signal lines include at least one first power line and a plurality of reference signal lines, and at least one reference signal line is located between two adjacent first power lines.

According to the embodiments of the present disclosure, the plurality of constant signal lines include at least one first power line and a plurality of reference signal lines, and the plurality of reference signal lines are located on a same side of the at least one first power line.

According to the embodiments of the present disclosure, the plurality of reference signal lines include at least one first reference signal line and at least one second reference signal line; the plurality of light emitting devices are arranged in an array in the first direction and the second direction, the light emitting devices arranged in the second direction have the same color, and the light emitting devices arranged in the first direction have different colors; the plurality of light emitting devices arranged in the second direction include a plurality of light emitting device groups arranged in the second direction, at least one light emitting device group includes a plurality of light emitting devices, different light emitting device groups include different light emitting devices, at least one light emitting device group is configured to display at least one disparity map group, and different light emitting device groups are configured to display different disparity map groups; and a distance between at least one first reference signal line and a second reference signal line adjacent to the at least one first reference signal line is greater than a size of the light emitting device group in the second direction.

According to the embodiments of the present disclosure, the plurality of pixel circuits in the at least one pixel circuit group are electrically connected to the light emitting devices in the plurality of light emitting device groups.

According to the embodiments of the present disclosure, the first reference signal line is electrically connected to first electrodes of the plurality of light emitting devices; and the display substrate includes a plurality of pixel circuit units, the first reference signal lines in two adjacent pixel circuit units are insulated and disconnected, and the second reference signal lines in the two adjacent pixel circuit units are communicated.

According to the embodiments of the present disclosure, the plurality of second separation regions include a plurality of first sub-regions and at least one second sub-region arranged in the second direction, the plurality of constant signal lines are located in the plurality of first sub-regions, a filling structure is provided in the at least one second sub-region, and the filling structure has a thickness substantially the same as a thickness of the constant signal line.

According to the embodiments of the present disclosure, the display substrate further includes a first pixel defining layer provided on the base substrate and a second pixel defining layer provided on a side of the first pixel defining layer away from the base substrate; the first pixel defining layer includes a first pixel opening extending in the first direction and a plurality of first defining portions located on two sides of the first pixel opening in the second direction, the second pixel defining layer includes a second pixel opening extending in the second direction and a plurality of second defining portions located on two sides of the second pixel opening in the first direction; the first pixel opening overlaps at least partially with the second pixel opening in a thickness direction of the display substrate so as to define a third pixel opening, and at least one light emitting device includes a light emitting portion located in the third pixel opening; and an orthographic projection of at least one constant signal line on the base substrate overlaps at least partially with an orthographic projection of at least one first defining portion on the base substrate.

According to the embodiments of the present disclosure, the orthographic projection of the at least one constant signal line on the base substrate is located within the orthographic projection of the at least one first defining portion on the base substrate.

According to the embodiments of the present disclosure, the display substrate further includes: a first conductive layer, a first insulation layer and a second conductive layer sequentially arranged in a direction away from the base substrate, the second conductive layer is located on a side of the first pixel defining layer close to the base substrate; at least one pixel circuit includes an input transistor, and the plurality of data lines are located in the second conductive layer; at least one data line is electrically connected to the input transistors of two pixel circuits adjacent in the second direction, through a first via hole penetrating the first insulation layer; and an orthographic projection of the first via hole on the base substrate is located within the orthographic projection of the at least one first defining portion on the base substrate.

According to the embodiments of the present disclosure, the at least one pixel circuit further includes a light emission control transistor; the plurality of constant signal lines include a first power line located in the second conductive layer; the first conductive layer includes a first power lead; the first power line is electrically connected to the first power lead through a second via hole penetrating the first insulation layer, and the light emission control transistors of the plurality of pixel circuits arranged in the second direction are electrically connected to a same first power lead; and an orthographic projection of the second via hole on the base substrate is located within the orthographic projection of the at least one first defining portion on the base substrate.

According to the embodiments of the present disclosure, the plurality of constant signal lines further include a plurality of reference signal lines, the plurality of reference signal lines include a first reference signal line located in the second conductive layer, and the at least one pixel circuit further includes a first reset transistor; the first conductive layer includes a first reference signal line lead; the first reference signal line is electrically connected to the first reference signal line lead through a third via hole penetrating the first insulation layer, and the first reset transistors of the plurality of pixel circuits arranged in the second direction are electrically connected to a same first reference signal line lead; and an orthographic projection of an overlapping portion of at least one first defining portion and at least one second defining portion on the base substrate defines a first pattern, and an orthographic projection of the third via hole on the base substrate is located within the first pattern.

According to the embodiments of the present disclosure, the plurality of reference signal lines further include a second reference signal line located in the second conductive layer, and the at least one pixel circuit further includes a second reset transistor; the first conductive layer includes a second reference signal line lead; the second reference signal line is electrically connected to the second reference signal line lead through a fourth via hole penetrating the first insulation layer, and the second reset transistors of the plurality of pixel circuits arranged in the second direction are electrically connected to a same second reference signal line lead; and an orthographic projection of the fourth via hole on the base substrate is located within an orthographic projection of the at least one second defining portion on the base substrate.

According to the embodiments of the present disclosure, the first insulation layer is provided with a plurality of first via holes and a plurality of fourth via holes, and an orthographic projection of at least one fourth via hole in the second direction overlaps partially with an orthographic projection of the plurality of first via holes in the second direction.

According to the embodiments of the present disclosure, the display substrate further includes a first electrode layer provided on a side of the second pixel defining layer away from the base substrate, and at least one light emitting device includes a first electrode located in the first electrode layer; and the first electrode of the at least one light emitting device includes a first edge and a second edge opposite to each other in the second direction, an orthographic projection of one of the first edge and the second edge on the base substrate overlaps at least partially with an orthographic projection of at least one data line on the base substrate, and an orthographic projection of the other of the first edge and the second edge on the base substrate overlaps at least partially with the orthographic projection of at least one constant signal line on the base substrate.

According to a second aspect of the present disclosure, a display panel is provided, including the display substrate as described above.

According to a second aspect of the present disclosure, a display device is provided, including the display panel as described above.

### BRIEF DESCRIPTION OF THE DRAWINGS

The above contents and other objectives, features and advantages of the present disclosure will be more apparent through the following descriptions of the embodiments of the present disclosure with reference to the accompanying drawings. In the accompanying drawings:

FIG. 1 schematically shows a plan view of a display substrate according to the embodiments of the present disclosure;

FIG. 2A schematically shows a first plan view of a pixel circuit unit according to the embodiments of the present disclosure;

FIG. 2B schematically shows a plan view of a light emitting device according to the embodiments of the present disclosure;

FIG. 3 schematically shows a second plan view of a pixel circuit unit according to the embodiments of the present disclosure;

FIG. 4 schematically shows a third plan view of a pixel circuit unit according to the embodiments of the present disclosure;

FIG. 5 schematically shows an equivalent circuit diagram of a pixel circuit according to the embodiments of the present disclosure;

FIG. 6 schematically shows a stack diagram of film layers of a display substrate according to the embodiments of the present disclosure;

FIG. 7 to FIG. 21 schematically show plan views of film layers of a pixel circuit according to the embodiments of the present disclosure;

FIG. 22 schematically shows a plan view of a third pixel opening according to the embodiments of the present disclosure; and

FIG. 23 schematically shows a schematic diagram of a display panel according to the embodiments of the present disclosure.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are just some embodiments rather than all embodiments of the present disclosure. Based on the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, a size and a relative size of an element may be enlarged. Accordingly, the size and relative size of each element need not to be limited to those shown in the drawings. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y and Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It should be noted that although the terms “first”, “second”, and so on may be used here to describe various components, members, elements, regions, layers and/or portions, these components, members, elements, regions, layers and/or portions should not be limited by these terms. Rather, these terms are used to distinguish one component, member, element, region, layer and/or portion from another. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, may be used here to describe a relationship between an element or feature and another element or feature as shown in the drawings. It should be understood that the spatial relationship terms are intended to cover other different orientations of a device in use or operation in addition to the orientation described in the drawings. For example, if a device in the drawing is turned upside down, an element or feature described as “below” or “under” another element or feature will be oriented “above” or “on” the another element or feature.

Herein, the terms “substantially”, “about”, “approximately”, “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used here includes a stated value and means that a specific value determined by those ordinary skilled in the art is within an acceptable range of deviation. For example, “about” may mean being within one or more standard deviations, or within ±30%, ±20%, ±10% or ±5% of the stated value.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or referred to as a size in a normal direction of the display device.

In an example, a display substrate is provided, and the display substrate may be applied to 3D display. The display substrate in this example includes a plurality of pixel units provided on the base substrate, and the plurality of pixel units are arranged in an array in a first direction and a second direction. Each pixel unit includes a plurality of groups of sub-pixels, and each group of sub-pixels includes a plurality of sub-pixels arranged in the second direction. Sub-pixels in a same group have the same color, and sub-pixels in different groups have different colors. A plurality of groups of sub-pixels in a same pixel unit are arranged in the first direction.

For example, a pixel unit includes three rows of sub-pixels, and each row of sub-pixels constitute a group. A first row of sub-pixels are red sub-pixels, a second row of sub-pixels are green sub-pixels, and a third row of sub-pixels are blue sub-pixels.

In a group of sub-pixels, each sub-pixel is a view. Each view may load a disparity map, and different views may load different disparity maps, which may achieve 3D display by matching with micro-lenses. The more views, the more disparity maps may be loaded, and the better the 3D display effect. Accordingly, the more views, the more sub-pixels, a space used for a layout of a signal line on the display substrate may decrease accordingly, so that a line width of the signal line may be limited, and a resistance of the signal line may be increased.

In view of this, the embodiments of the present disclosure provide a display substrate that may be applied to the 3D display, including: a base substrate; a pixel circuit unit provided on the base substrate, the pixel circuit unit includes a plurality of pixel circuit groups arranged in a first direction, and at least one pixel circuit group includes a plurality of pixel circuits and a plurality of separation regions; a plurality of light emitting devices provided on the base substrate and electrically connected to the plurality of pixel circuits, at least one pixel circuit is electrically connected to at least one light emitting device, different pixel circuits are electrically connected to different light emitting devices, the pixel circuits in a same pixel circuit group are electrically connected to light emitting devices having the same color, and the pixel circuits in different pixel circuit groups are electrically connected to light emitting devices having different colors; a plurality of data lines and a plurality of constant signal lines provided on the base substrate and electrically connected to the plurality of pixel circuits, the plurality of data lines and the plurality of constant signal lines extend in the first direction; the plurality of pixel circuits and the plurality of separation regions in a same pixel circuit group are alternately arranged in a second direction intersecting with the first direction; the plurality of separation regions include a plurality of first separation regions and a plurality of second separation regions, and the plurality of first separation regions and the plurality of second separation region are alternately arranged in the second direction; and the plurality of data lines are located in the plurality of first separation regions, different data lines are located in different first separation regions, two pixel circuits adjacent in the second direction share a same data line, the plurality of constant signal lines are located in the plurality of second separation regions, different constant signal lines are located in different second separation regions, and the plurality of pixel circuits in the pixel circuit unit share the plurality of constant signal lines.

In the embodiments of the present disclosure, in a pixel circuit unit, the separation region between adjacent pixel circuits is divided into alternating first separation regions and second separation regions. The first separation region is used to provide the data line, and two adjacent pixel circuits share the data line in the same first separation region, so that more space may be provided for a layout of constant signal lines on the display substrate. Specifically, all or part of the second separation regions in the plurality of separation regions may be used for the layout of constant signal lines, so that the number of constant signal lines may be increased, and a resistance on the constant signal line may be reduced. Meanwhile, in the embodiments of the present disclosure, different constant signal lines are located in different second separation regions, and the plurality of pixel circuits in the pixel circuit unit share the plurality of constant signal lines. In this way, it is possible to provide only one constant signal line in each second separation region, so that a line width of the constant signal line is not limited by other signal lines parallel to the constant signal line, thereby a design of the line width of the constant signal line may be flexible. For example, it is possible to increase the line width of the constant signal line to further reduce the resistance thereon, while the line width of the constant signal line may be close to a line width of the data line, which is conducive to making a segment difference in different separation regions to be substantially the same. For a display substrate in which a luminescent material is formed by printing, such structure is conducive to a printing uniformity.

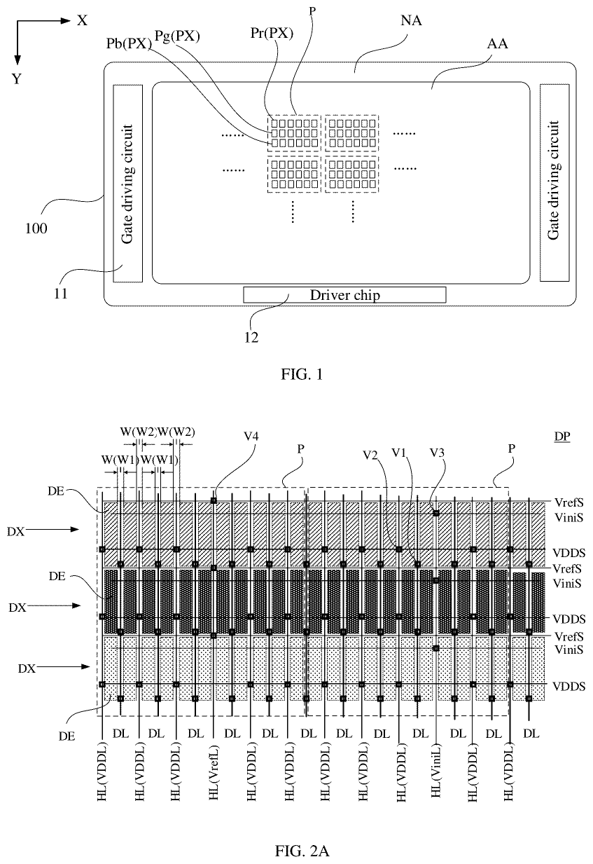

The display substrate of the embodiments of the present disclosure will be described in detail below with reference to FIG. 1 to FIG. 22.

The embodiments of the present disclosure provide a display substrate. FIG. 1 schematically shows a plan view of the display substrate according to the embodiments of the present disclosure.

Referring to FIG. 1, the display substrate of the embodiments of the present disclosure includes a display region AA and a peripheral region NA located on at least one side of the display region AA. The display region AA may have various shapes. For example, the display region AA may be provided in various shapes such as a closed polygon including straight sides (e.g., a rectangle), a circle, an ellipse, etc. that includes a curved side, and a semicircle, a semi-ellipse, etc. that includes a straight side and a curved side. In the embodiments of the present disclosure, the display region AA is provided as a region having a quadrangular shape including straight sides. It should be understood that this is just an exemplary embodiment of the present disclosure, rather than a limitation to the present disclosure.

The peripheral region NA may be arranged on at least one side of the display region AA. In the embodiments of the present disclosure, the peripheral region NA may surround a periphery of the display region AA. In the embodiments of the present disclosure, the peripheral region NA may include a longitudinal portion extending in a first direction Y and a transverse portion extending in a second direction X.

The display substrate may further include a gate driving circuit 11 and a driver chip 12, which are located in the peripheral region NA. For example, the gate driving circuit 11 may be located on at least one side of the display region AA. In the embodiments shown in FIG. 1, gate driving circuits 11are located on a left side and a right side of the display region AA, respectively. It should be noted that the left side and the right side may refer to a left side and a right side of the display substrate (screen) viewed by human eyes during display. For example, the driver chip 12 may be located on at least one side of the display region AA. In the embodiments shown in FIG. 1, the driver chip 12 is located on a lower side of the display region AA. It should be noted that the lower side may be a lower side of the display substrate (screen) viewed by human eyes during display.

The gate driving circuit 11 may be implemented by a shift register, and the gate driving circuit 11 may provide scanning signals to gate lines (not shown) on the display substrate. The driver chip 12 may provide data signals to data signal lines data L on the display substrate.

It should be noted that although FIG. 1 shows that the gate driving circuit 11 is located on the left side and the right side of the display region AA, and the driver chip 12 is located on the lower side of the display region AA. However, the embodiments of the present disclosure are not limited thereto. The gate driving circuit 11 and the driver chip 12 may be located at any suitable position in the peripheral region NA.

For example, a GOA technology, namely Gate Driver on Array, may be adopted for the gate driving circuit 11. In the GOA technology, the gate driving circuit 11 is provided directly on an array substrate to replace an external chip. The driver chip 12 may be folded to a back side of the display substrate through a structure such as chip on film.

Each GOA unit serves as a stage of shift register, and each stage of shift register is connected to a gate line. Scanning signals are sequentially output through stages of shift registers to achieve progressive scanning of pixel units. In some embodiments, each stage of shift register may also be connected to a plurality of gate lines. In this way, it may adapt to a development trend of high resolution and narrow bezel of display substrates.

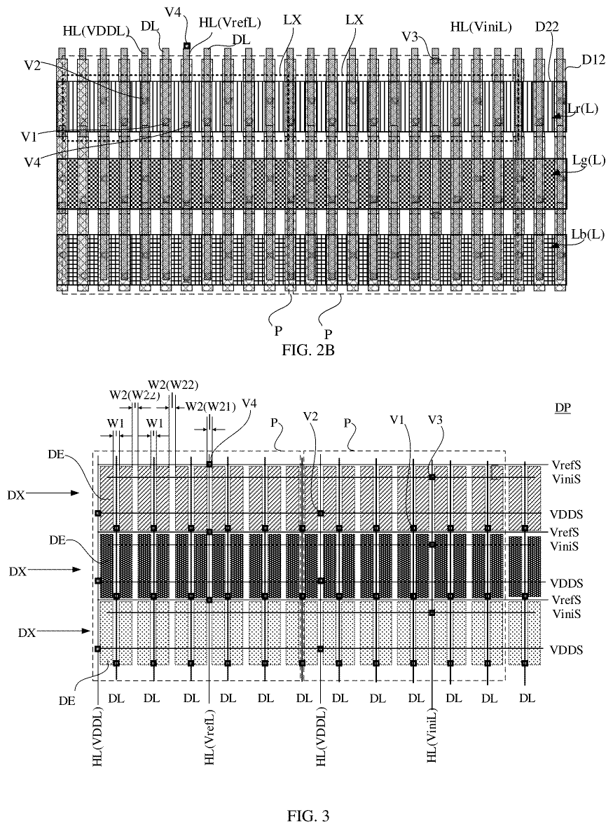

FIG. 2A schematically shows a first plan view of a pixel circuit unit according to the embodiments of the present disclosure.

The display substrate of the embodiments of the present disclosure may be applied to the 3D display. Referring to FIG. 1 and FIG. 2A, the display substrate further includes a base substrate 100 and a pixel circuit unit DP provided on the base substrate 100. The pixel circuit unit DP includes a plurality of pixel circuit groups DX arranged in the first direction Y, and at least one pixel circuit group DX includes a plurality of pixel circuits DE and a plurality of separation regions W. It should be noted that in the embodiments of the present disclosure, the display substrate may include a plurality of pixel circuit units DP, which may be arranged in an array in the first direction Y and the second direction X. The plurality of pixel circuit units DP have substantially the same structure. Therefore, in the embodiments of the present disclosure, unless otherwise specified, one pixel circuit unit DP is used as an example for explanation. For example, the first direction Y may be a vertical direction in FIG. 1, and the second direction X may be a horizontal direction in FIG. 1, that is, the first direction Y and the second direction X are perpendicular to each other.

FIG. 2B schematically shows a plan view of a light emitting device according to the embodiments of the present disclosure.

Referring to FIG. 1 and FIG. 2B, in the embodiments of the present disclosure, the display substrate further includes a plurality of light emitting devices L provided on the base substrate 100 and electrically connected to the plurality of pixel circuits DE. At least one pixel circuit DE is electrically connected to at least one light emitting device L, and different pixel circuits DE are electrically connected to different light emitting devices L. The pixel circuits DE in a same pixel circuit group DX are electrically connected to light emitting devices L having the same color, and the pixel circuits DE in different pixel circuit groups DX are electrically connected to light emitting devices L having different colors.

Exemplarily, a pixel circuit unit DP includes three rows of pixel circuits DE, and each row of pixel circuits DE constitute a pixel circuit group DX. The first row of pixel circuits DE may be electrically connected to light emitting devices Lr for emitting red light, the second row of pixel circuits DE may be electrically connected to light emitting devices Lg for emitting green light, and the third row of pixel circuits DE may be electrically connected to light emitting devices Lb for emitting blue light.

In the embodiments of the present disclosure, the display substrate includes a plurality of pixel units P, and at least one pixel unit P includes a plurality of sub-pixels PX. The plurality of sub-pixels PX include a plurality of sub-pixel groups arranged in the first direction Y, and a plurality of sub-pixels PX in a same sub-pixel group are arranged in the second direction X. A plurality of sub-pixels PX in a same sub-pixel group have the same color, and sub-pixels PX in different sub-pixel groups have different colors.

Exemplarily, a pixel unit P includes three rows of sub-pixels PX, and each row of sub-pixels PX form a sub-pixel group. A first row of sub-pixels PX may be described as red sub-pixels Pr, a second row of sub-pixels PX may be described as green sub-pixels Pg, and a third row of sub-pixels PX may be described as blue sub-pixels Pb.

Each sub-pixel PX may include a pixel circuit DE and a light emitting device L electrically connected to the pixel circuit DE. For example, the red sub-pixel Pr may include a first light emitting device L and a first pixel circuit DE electrically connected to the first light emitting device L, and the first light emitting device L may emit red light; the green sub-pixel Pg may include a second light emitting device L and a second pixel circuit DE electrically connected to the second light emitting device L, and the second light emitting device L may emit green light; the blue sub-pixel Pb may include a third light emitting device L and a third pixel circuit DE electrically connected to the third light emitting device L, and the third light emitting device L may emit blue light.

In a sub-pixel group, each sub-pixel is a view. Each view may load a disparity map, and different views may load different disparity maps, which may achieve the 3D display by matching with micro-lenses.

Exemplarily, a sub-pixel group may include eleven groups of sub-pixels PX, that is, include eleven views. Each view loads a disparity map, thereby eleven disparity maps may be loaded, so that a good 3D display effect may be achieved.

In the embodiments of the present disclosure, from a perspective of display driving signals, each pixel unit P form a repetitive unit. However, when designing wires, a pixel circuit unit DP acts as a repetitive unit, a pixel circuit unit DP may include a pixel circuit DE for a plurality of pixel units P. For example, a pixel unit P may include three sub-pixel groups, and each sub-pixel group includes eleven sub-pixels PX, that is, a pixel unit P includes eleven pixel circuits DE in the second direction X. A pixel circuit unit DP includes three pixel circuit groups DX, and each pixel circuit group DX includes twenty-four pixel circuits DE, that is, a pixel circuit unit DP may include twenty-four pixel circuits DE in the second direction X.

The display substrate of the embodiments of the present disclosure further includes a plurality of data lines DL and a plurality of constant signal lines HL provided on the base substrate 100 and electrically connected to the plurality of pixel circuits DE. The plurality of data lines DL and the plurality of constant signal lines HL extend in the first direction Y.

In the embodiments of the present disclosure, the constant signal line HL may refer to a signal line that maintains a constant signal during a display process. For example, the constant signal line HL may include a first power line VDDL for providing a high-level voltage signal and a reference signal line (such as a first reference signal line ViniL and a second reference signal line VrefL) for resetting.

In the embodiments of the present disclosure, a plurality of pixel circuits DE and a plurality of separation regions W in a same pixel circuit group DX are alternately arranged in the second direction X.

Referring to FIG. 2A, in a pixel circuit group DX, a separation region W is provided between each two adjacent pixel circuits DE, and the plurality of separation regions W are used for a lay out of signal lines extending in the first direction Y on the display substrate, such as the above-mentioned data lines DL and constant signal lines HL.

The plurality of separation regions W include a plurality of first separation regions W1 and a plurality of second separation regions W2, and the plurality of first separation regions W1 and the plurality of second separation regions W2 are alternately arranged in the second direction X. The plurality of data lines DL are located in the plurality of first separation regions W1, different data lines DL are located in different first separation regions W1, and two pixel circuits DE adjacent in the second direction X share the same data line DL. The plurality of constant signal lines HL are located in the plurality of second separation regions W2, different constant signal lines HL are located in different second separation regions W2, and the plurality of pixel circuits DE in the pixel circuit unit DP share the plurality of constant signal lines HL.

In the embodiments of the present disclosure, in a pixel circuit unit DP, the separation region W between adjacent pixel circuits DE is divided into alternating first separation regions W1 and second separation regions W2. The first separation region W1 is used to provide the data line DL, and two adjacent pixel circuits DE share the data line DL in the same first separation region W1, so that more space may be provided for a layout of constant signal lines HL on the display substrate. Specifically, all or part of the second separation regions W2 in the plurality of separation regions W may be used for the layout of constant signal lines HL, so that the number of constant signal lines HL may be increased, and the resistance on the constant signal lines HL may be reduced. Meanwhile, in the embodiments of the present disclosure, different constant signal lines HL are located in different second separation regions W2, and the plurality of pixel circuits DE in the pixel circuit unit DP share the plurality of constant signal lines HL. In this way, it is possible to provide only one constant signal line HL in each second separation region W2, so that a line width of the constant signal line HL is not limited by other signal lines parallel to the constant signal line HL, and a design of the line width of the constant signal line HL may be flexible. For example, it is possible to increase the line width of the constant signal line HL to further reduce the resistance thereon, and the line width of the constant signal line HL may be close to a line width of the data line DL, so that a segment difference may be substantially the same in different separation regions W. For a display substrate in which a luminescent material is formed by printing, such structure is conducive to a printing uniformity.

In summary, the embodiments of the present disclosure provide a display substrate that may be applied to the 3D display. In such display substrate, a plurality of views may be provided in a pixel unit P to achieve a good 3D display effect. On this basis, compared to a traditional display substrate used for the 3D display, the display substrate of the present disclosure increases the number of constant signal lines HL and also increases a design space for the line width of the constant signal line HL, thereby further reducing the resistance on the constant signal line HL, alleviating a voltage drop and other problems, facilitating the uniformity of printing the luminescent material, and improving the display effect.

The display substrate of the embodiments of the present disclosure will be further described below with reference to FIG. 1 to FIG. 22.

In some specific embodiments, a plurality of signal lines are provided on the display substrate. The plurality of signal lines include scanning lines (such as gate lines and light emission control lines, etc.) extending in the second direction X, and further include a plurality of data lines DL and a plurality of constant signal lines HL extending in the first direction Y. Exemplarily, the plurality of constant signal lines HL may include a plurality of first power lines VDDL for providing high-level voltage signals and a plurality of reference signal lines (such as first reference signal lines ViniL and second reference signal lines VrefL) for resetting.

Referring to FIG. 2A, a distance between at least one reference signal line and a first power line VDDL adjacent to the at least one reference signal line is substantially the same as a distance between two adjacent data lines DL. For example, two adjacent data lines DL are located on two sides of a pixel circuit DE. Accordingly, at least one reference signal line and a first power line VDDL adjacent to the at least one reference signal line are also located on two sides of a pixel circuit DE.

The first power line VDDL being adjacent to the reference signal line may refer to that no other first power line VDDL is provided between the two. The distance between the reference signal line and the first power line VDDL may refer to an average distance between the two in the second direction X, and the distance between two adjacent data lines DL may refer to an average size between the two in the second direction X.

In some specific embodiments, a distance between two adjacent first power lines VDDL is substantially the same as the distance between two adjacent data lines DL. Two adjacent first power lines VDDL may refer to that no other first power line VDDL is provided between the two. The distance between two adjacent first power lines VDDL may refer to an average size between the two in the second direction X.

For example, each two of the plurality of constant signal lines HL are spaced by the same distance, and that distance is the same as the distance between two adjacent data lines DL. In this way, the plurality of constant signal lines HL and data lines DL may be arranged at equal intervals, so that the plurality of constant signal lines HL may be closely arranged, then as many constant signal lines HL as possible may be provided on the display substrate, thereby greatly reducing the resistance on the constant signal line HL. For example, referring to FIG. 2A and FIG. 2B, a pixel circuit unit DP includes twenty-four columns and three rows of pixel circuits DE, and each row of pixel circuits DE form a pixel circuit group DX. A first row of pixel circuits DE are connected to light emitting devices Lr for emitting red light, a second row of pixel circuits DE are connected to light emitting devices Lg for emitting green light, and a third row of pixel circuits DE are connected to light emitting devices Lb for emitting blue light. Each second separation region of the pixel circuit unit DP is provided with a constant signal line HL. For example, ten first power lines VDDL, one first reference signal line ViniL and one second reference signal line VrefL may be provided. Each first power line VDDL is equivalent to providing electrical signals to 2.4 columns of pixel circuits DE. As the number of first power lines VDDL increases, the resistance on the first power line VDDL may be decreased, and the corresponding voltage drop (IR Drop) may also be decreased.

Optionally, the line width of the constant signal line HL may be substantially the same as the line width of the data line DL, so that a wiring layout may be substantially consistent on left and right sides of the plurality of pixel circuits DE, thereby ensuring consistency of a printing environment to a great extent.

Optionally, two columns of pixel circuits DE (in other words, two adjacent groups of pixel circuits DE) on two sides of a first separation region W1 may share one or more data lines DL in that first separation region W1. For clarity, unless otherwise specified, a first separation region W1 being provided with one data line DL is used as example for description. In other words, two adjacent groups of pixel circuits DE share one data line DL in the first separation region W1.

Optionally, a row of pixel circuits DE may be provided with two gate lines, one is used to control turn-on or turn-off of input transistors of odd-numbered columns of pixel circuits DE, and the other is used to control turn-on or turn-off of input transistors of even-numbered columns of pixel circuits DE, thereby achieving time division multiplexing of one data line DL by two pixel circuits DE.

FIG. 3 schematically shows a second plan view of a pixel circuit unit according to the embodiments of the present disclosure.

Referring to FIG. 3, in other specific embodiments, the distance between two adjacent constant signal lines HL is greater than the distance between two adjacent data lines DL. Compared to the aforementioned embodiments, the distance between constant signal lines HL in this embodiment is increased, so that the plurality of constant signal lines HL may be arranged in a relatively loose manner. In this way, it is possible to appropriately reduce the space occupied by the constant signal lines HL, and provide a deployment space for other devices so as to increase a design flexibility.

In some specific embodiments, the plurality of constant signal lines HL include at least one first power line VDDL and a plurality of reference signal lines (such as the first reference signal line ViniL and the second reference signal line VrefL), and at least one reference signal line is located between two adjacent first power lines VDDL. Exemplarily, a reference signal line may be provided between each two adjacent first power lines VDDL. In this way, more first power lines VDDL (compared to the reference signal lines) may be provided on the display substrate, so that the resistance on the first power line VDDL may be minimized, and the problem of voltage drop on the first power line VDDL may be improved.

In some specific embodiments, the plurality of constant signal lines HL may be arranged at equal intervals, so that the plurality of constant signal lines HL may be uniformly arranged on the display substrate.

Exemplarily, referring to FIG. 3, a pixel circuit unit DP includes twenty-four columns and three rows of pixel circuits DE, and each row of pixel circuits DE form a pixel circuit group DX. A first row of pixel circuits DE are connected to light emitting devices Lr for emitting red light, a second row of pixel circuits DE are connected to light emitting devices Lg for emitting green light, and a third row of pixel circuits DE are connected to light emitting devices Lb for emitting blue light. Constant signal lines HL, such as two first power lines VDDL, one first reference signal line ViniL and one second reference signal line VrefL are provided in part of the second separation regions in the pixel circuit unit DP. Each first power line VDDL is equivalent to providing electrical signals to twelve columns of pixel circuits DE. Compared to the aforementioned embodiments, the constant signal lines HL in this embodiment may be arranged in a more loose manner, so that more space may be provided for other devices.

FIG. 4 schematically shows a third plan view of a pixel circuit unit according to the embodiments of the present disclosure.

Referring to FIG. 4, in other specific embodiments, the plurality of constant signal lines HL include at least one first power line VDDL and a plurality of reference signal lines (such as the first reference signal line ViniL and the second reference signal line VrefL), and the plurality of reference signal lines are located on a same side of the at least one first power line VDDL.

For example, the first reference signal line ViniL may be located between the second reference signal line VrefL and the first power line VDDL. In other words, the second reference signal line VrefL and the first power line VDDL may be located at two ends of the pixel circuit unit DP respectively, which is conducive to a connection between the second reference signal lines VrefL of two pixel circuit units DP adjacent in the second direction X and the first power line VDDL. For the first reference signal line ViniL, the first reference signal lines ViniL in two pixel circuit units DP adjacent in the second direction X may be insulated and separated. Therefore, the first reference signal line ViniL may be arranged in the middle of the pixel circuit unit DP.

Exemplarily, referring to FIG. 4, a pixel circuit unit DP includes twenty-four columns and three rows of pixel circuits DE, and each row of pixel circuits DE form a pixel circuit group DX. A first row of pixel circuits DE are connected to light emitting devices Lr for emitting red light, a second row of pixel circuits DE are connected to light emitting devices Lg for emitting green light, and a third row of pixel circuits DE are connected to light emitting devices Lb for emitting blue light. Constant signal lines HL, such as one first power line VDDL, one first reference signal line ViniL and one second reference signal line VrefL are provided in part of the second separation regions in the pixel circuit unit DP. Each first power line VDDL is equivalent to providing electrical signals to twenty-four columns of pixel circuits DE. Compared to the aforementioned embodiments, a smallest number of constant signal lines HL are provided in this embodiment, thereby maximizing the space for other devices.

Referring to FIG. 2 to FIG. 4, in some specific embodiments, the plurality of reference signal lines include at least one first reference signal line ViniL and at least one second reference signal line VrefL. A plurality of light emitting devices L are arranged in an array in the first direction Y and the second direction X. The light emitting devices L arranged in the second direction X have the same color, and the light emitting devices L arranged in the first direction Y have different colors.

Referring to FIG. 2B, for example, a plurality of light emitting devices L electrically connected to a pixel circuit unit DP include twenty-four columns and three rows of light emitting devices L. The twenty-four columns and three rows of light emitting devices L include light emitting devices Lr for emitting red light, light emitting devices Lg for emitting green light, and light emitting devices Lb for emitting blue light. The light emitting devices Lr for emitting red light are located in a first row, the light emitting devices Lg for emitting green light are located in a second row, and the light emitting devices Lb for emitting blue light are located in a third row.

The plurality of light emitting devices L arranged in the second direction include a plurality of light emitting device groups LX arranged in the second direction, and at least one light emitting device group LX includes a plurality of light emitting devices L. Different light emitting device groups LX include different light emitting devices L. At least one light emitting device group LX is used to display at least one group of disparity maps, and different light emitting device groups LX are used to display different groups of disparity maps.

In the embodiments of the present disclosure, each light emitting device L may display a disparity map. For example, a disparity map group includes eleven disparity maps, a light emitting device group LX may include eleven light emitting devices L, and each light emitting device L is used as a view to display one of the disparity maps. In other words, the light emitting devices L in a light emitting device group LX are also the light emitting devices L of all sub-pixels PX in a sub-pixel group as described above. For example, a sub-pixel group includes eleven sub-pixels PX, and eleven light emitting devices L of the eleven sub-pixels PX form a light emitting device group LX.

In the embodiments of the present disclosure, a distance between at least one first reference signal line ViniL and a second reference signal line VrefL adjacent to the first reference signal line ViniL is greater than a size of the light emitting device group LX in the second direction X.

For example, referring to FIG. 2A to FIG. 4, a first reference signal line ViniL and a second reference signal line VrefL adjacent to the first reference signal line ViniL are spaced by twelve columns of pixel circuits DE. A light emitting device group LX covers eleven columns of pixel circuits DE in the second direction X. Therefore, the first reference signal line ViniL and the second reference signal line VrefL adjacent to the first reference signal line ViniL are respectively located in two light emitting device groups LX, so as to provide corresponding electrical signals to light emission of the light emitting devices L in at least two light emitting device groups LX through the corresponding pixel circuits DE.

In some specific embodiments, a plurality of pixel circuits DE in at least one pixel circuit group DX are electrically connected to light emitting devices L in a plurality of light emitting device groups LX. For example, a pixel circuit group DX includes twenty-four columns of pixel circuits DE, and a light emitting device group LX includes eleven light emitting devices L. The twenty-four columns of pixel circuits DE in the pixel circuit group DX are respectively electrically connected to the eleven light emitting devices L in first two light emitting device groups LX and to first two light emitting devices L in a third light emitting device group LX (a total of twenty-four light emitting devices L).

Optionally, through a reference signal line lead (such as a first reference signal line lead ViniS and a second reference signal line lead VrefS) extending in the second direction X, a plurality of pixel circuits DE in a pixel circuit unit DP may share the first reference signal line ViniL and the second reference signal line VrefL.

In some specific embodiments, the first reference signal line ViniL is electrically connected to first electrodes of a plurality of light emitting devices L. The display substrate includes a plurality of pixel circuit units DP, the first reference signal lines ViniL in two adjacent pixel circuit units DP are insulated and disconnected, and the second reference signal lines VrefL in two adjacent pixel circuit units DP are communicated.

Optionally, the first power lines VDDL in two adjacent pixel circuit units DP are communicated. For example, the first power lines VDDL in a plurality of pixel circuit units DP may be communicated through the second reference signal line lead VrefS and a first power line lead VDDS extending in the second direction X.

Referring to FIG. 3 and FIG. 4, in some specific embodiments, the plurality of second separation regions W2 include a plurality of first sub-regions W21 and a plurality of second sub-regions W22 arranged in the second direction X. The plurality of constant signal lines HL are located in the plurality of first sub-regions W21, and at least one second sub-region W22 is provided with a filling structure. The filling structure has a thickness substantially the same as a thickness of the constant signal line HL.

In the embodiments of the present disclosure, the second sub-region W22 may have the same width as the first sub-region W21. A difference between the second sub-region W22 and the first sub-region W21 is that no constant signal line HL is provided in the second sub-region W22. At a position corresponding to the constant signal line HL in the second sub-region W22, a filling structure may be formed using a pixel defining layer so as to maintain consistency in a film layer height between the first sub-region W21 and the second sub-region W22.

Referring to FIG. 3, in a pixel circuit unit DP, a plurality of second sub-regions W22 are provided between two adjacent first sub-regions W21.

In the embodiments of the present disclosure, the number of first sub-regions W21 and second sub-regions W22 may be set according to actual needs. For example, when the problem of voltage drop on the first power line VDDL is sensitive, it is possible to provide more first power lines VDDL, then the number of first sub-regions W21 increases and the number of second sub-regions W22 decreases. Accordingly, when the problem of voltage drop on the first power line VDDL is not sensitive, it is possible to provide less first power lines VDDL, then the number of first sub-regions W21 decreases and the number of second sub-regions W22 increases.

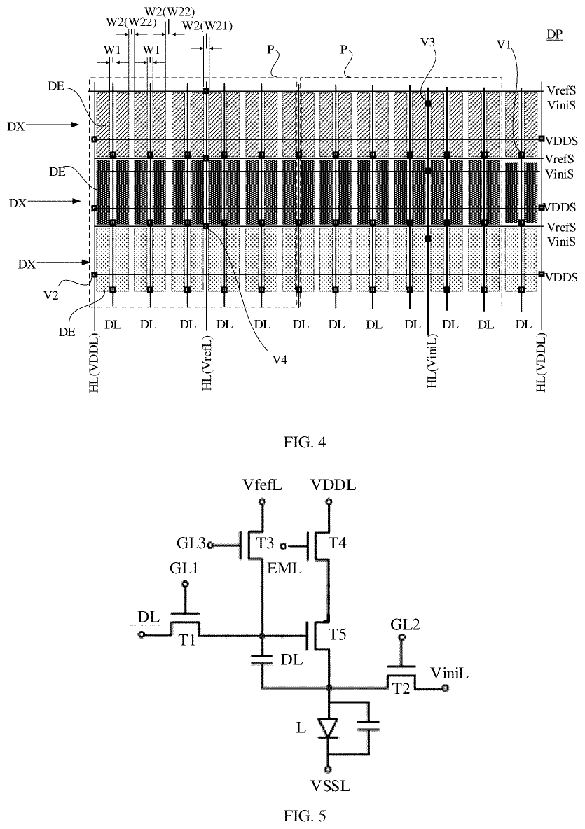

FIG. 5 schematically shows an equivalent circuit diagram of a pixel circuit according to the embodiments of the present disclosure.

Referring to FIG. 5, the pixel circuit DE may include an input transistor T1, a first reset transistor T2, a second reset transistor T3, a light emission control transistor T4, a driving transistor T5, and a storage capacitor Cst. Such pixel circuit DE may be referred to as a 5T1C structure.

It should be noted that in the embodiments of the present disclosure, the 5T1C structure is illustrated by way of example in describing the pixel circuit DE of the embodiments of the present disclosure, but does not constitute a limitation to the embodiments of the present disclosure. Other structures such as 7T1C may also be adopted for the pixel circuit DE of the embodiments of the present disclosure, which will not be listed in detail here.

It should also be noted that the transistors used in the embodiments of the present disclosure may be thin film transistors, field-effect transistors, or other devices having the same characteristics. In the following descriptions, one of a first electrode and a second electrode of a transistor may refer to a source electrode of the transistor, and the other refers to a drain electrode of the transistor. The source electrode and the drain electrode of the thin film transistor used here are symmetrical and therefore may be interchanged.

In the embodiments of the present disclosure, the input transistor T1 has a first electrode electrically connected to a data line DL, a second electrode electrically connected to a gate electrode of the driving transistor T5, and a gate electrode electrically connected to a first scanning line GL1.

The driving transistor T5 has a first electrode electrically connected to a second electrode of the light emission control transistor T4, and a second electrode electrically connected to a first electrode of the light emitting device L. The gate electrode of the driving transistor T5 is further electrically connected to a first electrode plate of the storage capacitor Cst. The light emitting device L has a second electrode electrically connected to a second power line VSSL. The storage capacitor Cst has a second electrode plate connected between the second electrode of the driving transistor T5 and the light emitting device L.

The first reset transistor T2 has a first electrode electrically connected to the first reference signal line ViniL, a second electrode electrically connected to the second electrode of the driving transistor T5, and a gate electrode electrically connected to a second scanning line GL2.

The second reset transistor T3 has a first electrode electrically connected to the second reference signal line VrefL, a second electrode electrically connected to the gate electrode of the driving transistor T5, and a gate electrode electrically connected to a third scanning line GL3.

The light emission control transistor T4 has a first electrode electrically connected to the first power line VDDL, a second electrode electrically connected to the first electrode of the driving transistor T5, and a gate electrode electrically connected to a light emission control line EML.

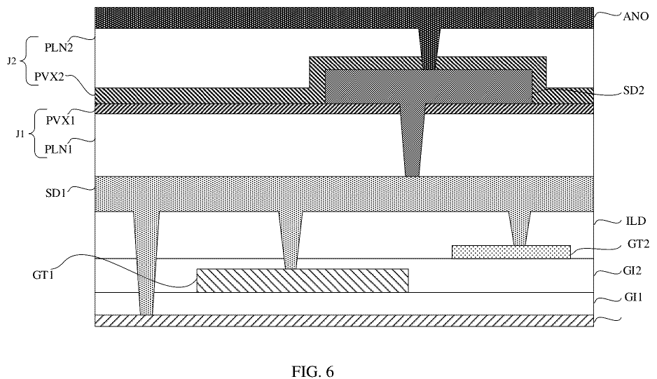

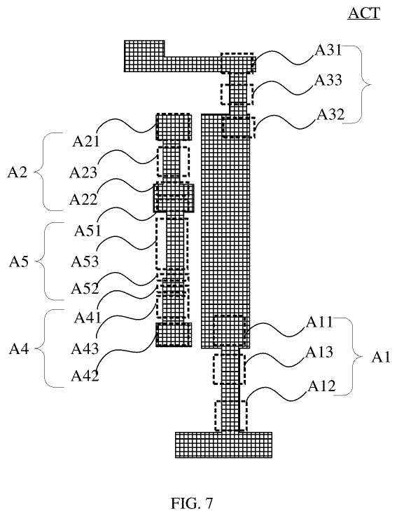

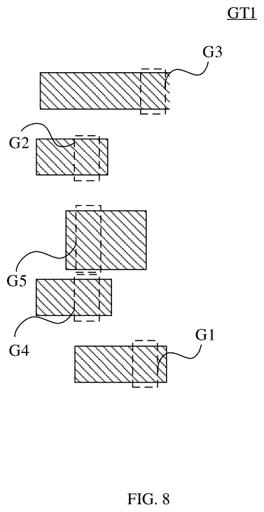

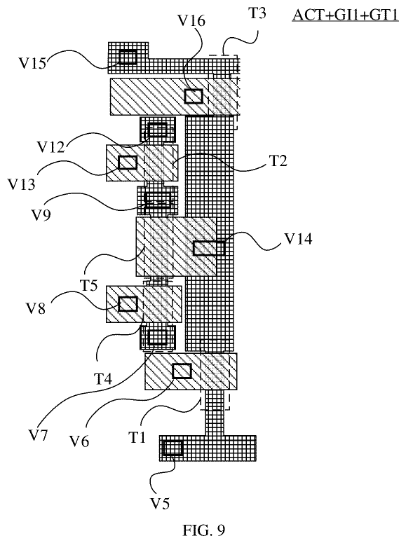

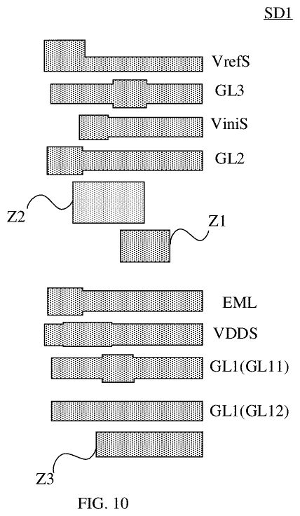

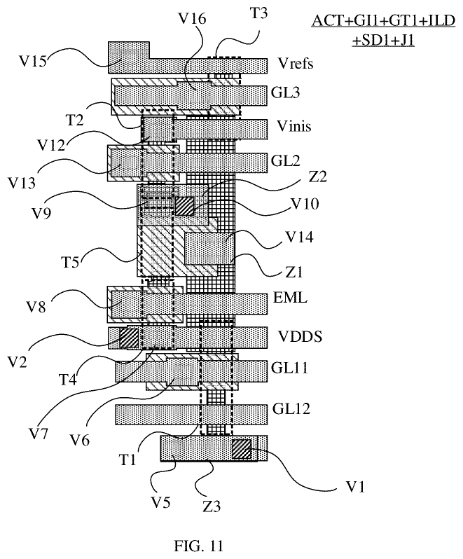

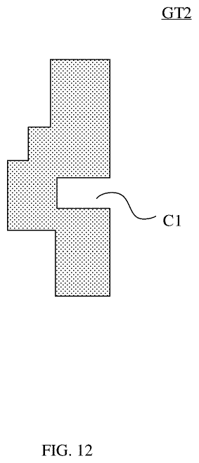

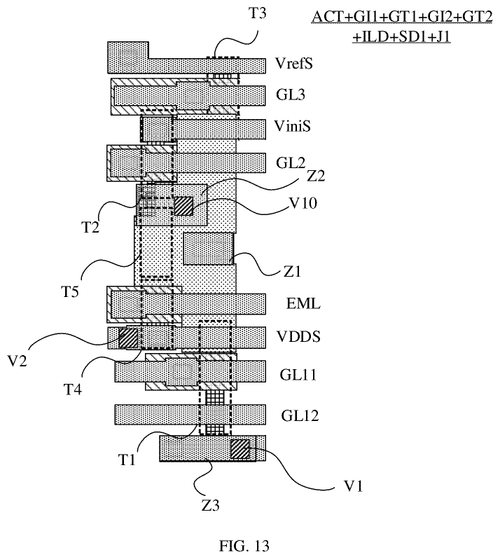

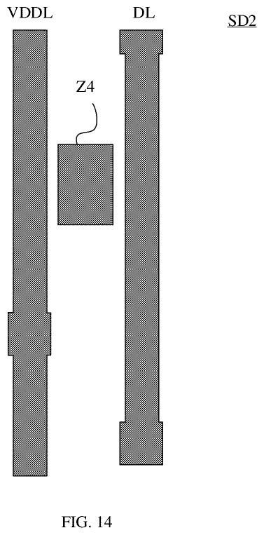

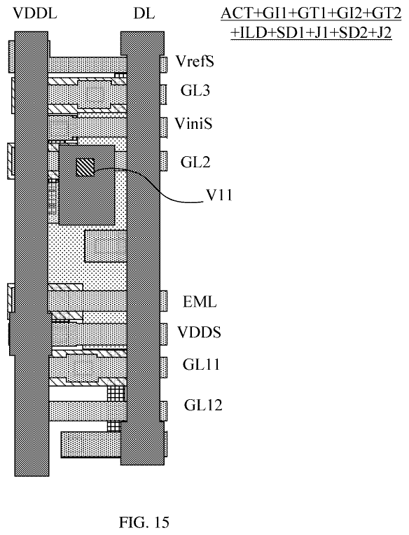

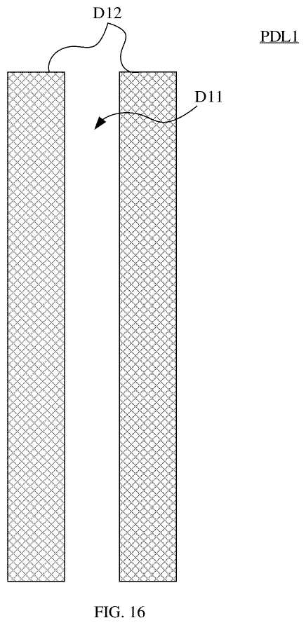

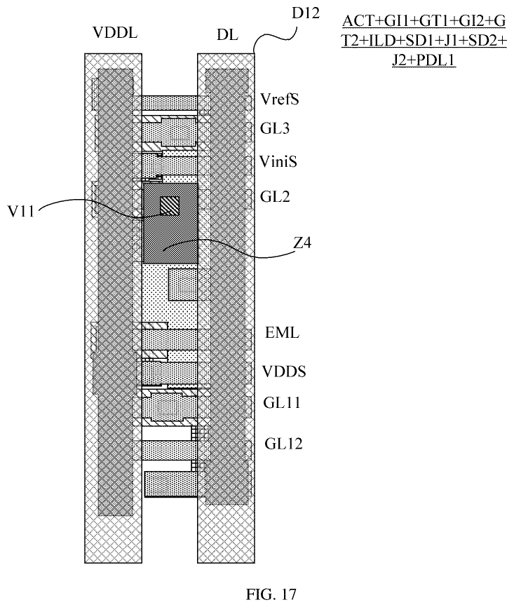

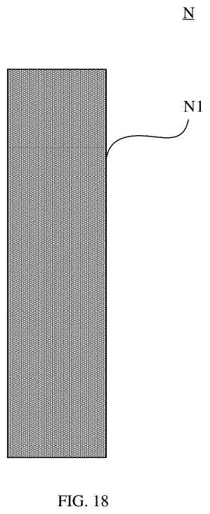

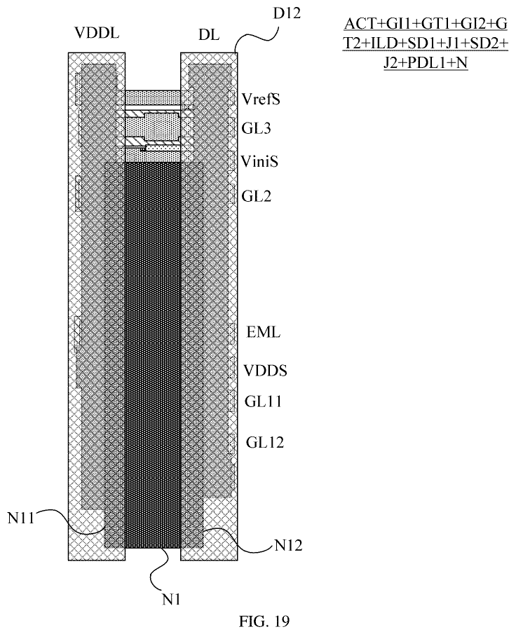

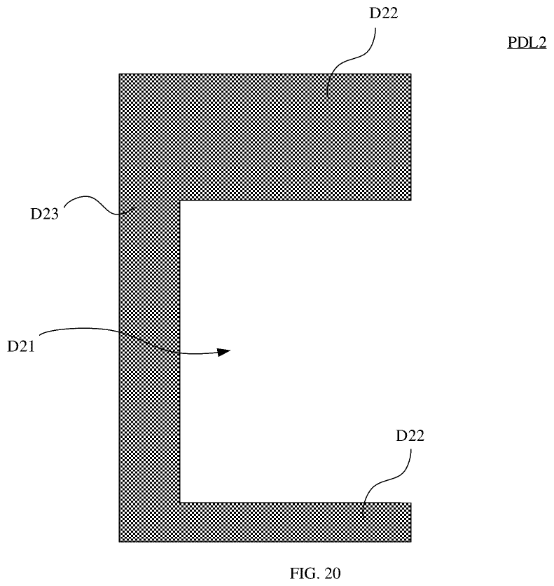

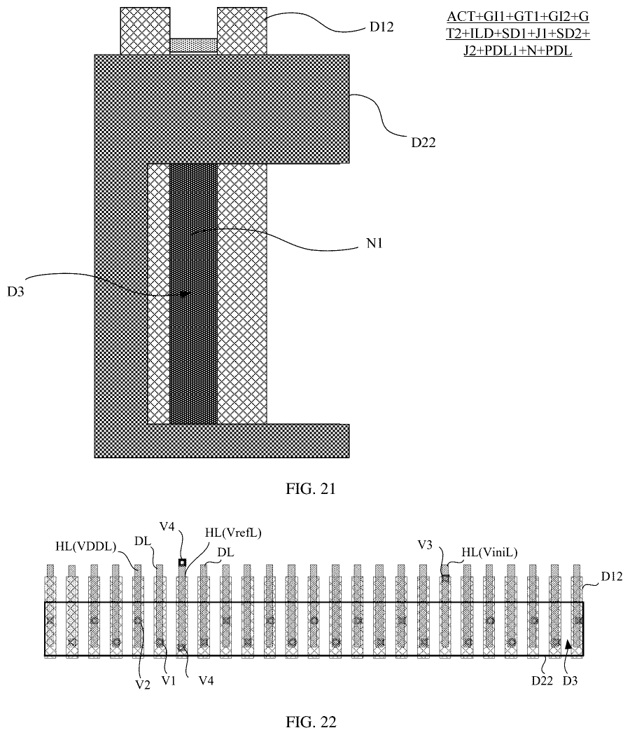

FIG. 6 schematically shows a stack diagram of film layers of a display substrate according to the embodiments of the present disclosure. FIG. 7 to FIG. 21 schematically show plan views of film layers of a pixel circuit according to the embodiments of the present disclosure, in which: FIG. 7 schematically shows a plan view of a semiconductor layer according to the embodiments of the present disclosure, FIG. 8 schematically shows a plan view of a first gate layer according to the embodiments of the present disclosure, FIG. 9 schematically shows a plan view of a semiconductor layer, a first gate insulation layer and a first gate layer according to the embodiments of the present disclosure, FIG. 10 schematically shows a plan view of a first conductive layer according to the embodiments of the present disclosure, FIG. 11 schematically shows a plan view of a semiconductor layer, a first gate insulation layer, a first gate layer, an interlayer dielectric layer, a first conductive layer and a first insulation layer according to the embodiments of the present disclosure, FIG. 12 schematically shows a plan view of a second gate layer according to the embodiments of the present disclosure, FIG. 13 schematically shows a plan view of a semiconductor layer, a first gate insulation layer, a first gate layer, a second gate insulation layer, a second gate layer, an interlayer dielectric layer, a first conductive layer and a first insulation layer according to the embodiments of the present disclosure, FIG. 14 schematically shows a plan view of a second conductive layer according to the embodiments of the present disclosure, FIG. 15 schematically shows a plan view of a semiconductor layer, a first gate insulation layer, a first gate layer, a second gate insulation layer, a second gate layer, an interlayer dielectric layer, a first conductive layer, a first insulation layer, a second conductive layer and a second insulation layer according to the embodiments of the present disclosure, FIG. 16 schematically shows a plan view of a first pixel defining layer according to the embodiments of the present disclosure, FIG. 17 schematically shows a plan view of a semiconductor layer, a first gate insulation layer, a first gate layer, a second gate insulation layer, a second gate layer, an interlayer dielectric layer, a first conductive layer, a first insulation layer, a second conductive layer, a second insulation layer and a first pixel defining layer according to the embodiments of the present disclosure, FIG. 18 schematically shows a plan view of a first electrode layer according to the embodiments of the present disclosure, FIG. 19 schematically shows a plan view of a semiconductor layer, a first gate insulation layer, a first gate layer, a second gate insulation layer, a second gate layer, an interlayer dielectric layer, a first conductive layer, a first insulation layer, a second conductive layer, a second insulation layer, a first pixel defining layer and a first electrode layer according to the embodiments of the present disclosure, FIG. 20 schematically shows a plan view of a second pixel defining layer according to the embodiments of the present disclosure, and FIG. 21 schematically shows a plan view of a semiconductor layer, a first gate insulation layer, a first gate layer, a second gate insulation layer, a second gate layer, an interlayer dielectric layer, a first conductive layer, a first insulation layer, a second conductive layer, a second insulation layer, a first pixel defining layer, a first electrode layer and a second pixel defining layer according to the embodiments of the present disclosure.

It should be noted that some drawings mainly schematically show a via hole in an insulation film layer without showing an insulation material itself of the insulation film layer. In this way, a position of the via hole in the insulation film layer is highlighted.

Planar structures of the pixel circuit DE, the data line and the constant signal line in the embodiments of the present disclosure will be described below with reference to FIG. 6 to FIG. 21.

It should be noted that for ease of description, unless otherwise specified, a pixel circuit DE and the signal lines and related structures (such as via holes) electrically connected to the pixel circuit DE are taken as an example below for description.

In some specific embodiments, the display substrate includes a semiconductor layer ACT, a first gate insulation layer GI1, a first gate layer GT1, a second gate insulation layer GI2, a second gate insulation layer GT2, an interlayer dielectric layer ILD, a first conductive layer SD1, a first insulation layer J1, a second conductive layer SD2, a second insulation layer J2, and a first electrode layer N, which are provided on the base substrate 100 and sequentially arranged in a direction away from the base substrate 100.

For example, the conductive film layer in the above-mentioned film layers may be made of a metal material, such as silver, copper, aluminum, molybdenum, etc., or an alloy material of the above-mentioned metals, such as aluminum niobium alloy, molybdenum niobium alloy, etc., or may be multi-layer metals, such as Mo/Cu/Mo, etc., or may be a stack structure formed by metals and transparent conductive materials, such as ITO/Ag/ITO, etc.

The semiconductor layer ACT may include materials such as amorphous silicon, polycrystalline silicon, or oxide semiconductors, and may include, for example, a channel portion, a first electrode connecting portion, and a second electrode connecting portion. The channel portion may not be doped or may have a different doping type from the first electrode connecting portion and the second electrode connecting portion, and therefore has semiconductor characteristics. The first electrode connecting portion and the second electrode connecting portion are respectively located on two sides of the channel portion and are doped with impurities, and therefore have conductivity. The impurities may vary depending on whether the TFT is an N-type transistor or a P-type transistor.

In the embodiments of the present disclosure, the input transistor T1 includes a first active portion A1 located in the semiconductor layer ACT, the first reset transistor T2 includes a second active portion A2 located in the semiconductor layer ACT, the second reset transistor T3 includes a third active portion A3 located in the semiconductor layer ACT, the light emission control transistor T4 includes a fourth active portion A4 located in the semiconductor layer ACT, and the driving transistor T5 includes a fifth active portion A5 located in the semiconductor layer ACT.

In the embodiments of the present disclosure, the input transistor T1 further includes a first gate electrode G1 located in the first gate layer GT1, the first reset transistor T2 further includes a second gate electrode G2 located in the first gate layer GT1, the second reset transistor T3 further includes a third gate electrode G3 located in the first gate layer GT1, the light emission control transistor T4 further includes a fourth gate electrode G4 located in the first gate layer GT1, and the driving transistor T5 further includes a fifth gate electrode G5 located in the first gate layer GT1.

In the embodiments of the present disclosure, the first active portion A1 includes a first electrode connecting portion A11, a second electrode connecting portion A12, and a channel portion A13 located between the first electrode connecting portion A11 and the second electrode connecting portion A12. The channel portion A13 of the first active portion A1 is directly opposite to the first gate electrode G1. The first electrode connecting portion A11, the channel portion A13 and the second electrode connecting portion A12 of the first active portion A1 are arranged in the first direction Y.

In the embodiments of the present disclosure, the second active portion A2 includes a first electrode connecting portion A21, a second electrode connecting portion A22, and a channel portion A23 located between the first electrode connecting portion A21 and the second electrode connecting portion A22. The channel portion A23 of the second active portion A2 is directly opposite to the second gate electrode G2. The first electrode connecting portion A21, the channel portion A23 and the second electrode connecting portion A22 of the first active portion A1 are arranged in the first direction Y.

In the embodiments of the present disclosure, the third active portion A3 includes a first electrode connecting portion A31, a second electrode connecting portion A32, and a channel portion A33 located between the first electrode connecting portion A31 and the second electrode connecting portion A32. The channel portion A33 of the third active portion A3 is directly opposite to the third gate electrode G3. The first electrode connecting portion A31, the channel portion A33 and the second electrode connecting portion A32 of the third active portion A3 are arranged in the first direction Y.

In the embodiments of the present disclosure, the fourth active portion A4 includes a first electrode connecting portion A41, a second electrode connecting portion A42, and a channel portion A43 located between the first electrode connecting portion A41 and the second electrode connecting portion A42. The channel portion A43 of the fourth active portion A4 is directly opposite to the fourth gate electrode G4. The first electrode connecting portion A41, the channel portion A43 and the second electrode connecting portion A42 of the fourth active portion A4 are arranged in the first direction Y.

In the embodiments of the present disclosure, the fifth active portion A5 includes a first electrode connecting portion A51, a second electrode connecting portion A52, and a channel portion A53 located between the first electrode connecting portion A51 and the second electrode connecting portion A52. The channel portion A53 of the fifth active portion A5 is directly opposite to the fifth gate electrode G5. The first electrode connecting portion A51, the channel portion A53 and the second electrode connecting portion A52 of the fifth active portion A5 are arranged in the first direction Y.

In some specific embodiments, the second active portion A2, the fifth active portion A5 and the fourth active portion A4 are sequentially arranged in the first direction Y. An orthographic projection of the second electrode connecting portion A32 of the third active portion A3 in the second direction X overlaps at least partially with an orthographic projection of the first electrode connecting portion A21 of the second active portion A2 in the second direction X.

In some specific embodiments, an orthographic projection of the second electrode connecting portion A12 of the first active portion A1 in the second direction X overlaps at least partially with an orthographic projection of the first electrode connecting portion A41 of the fourth active portion A4 in the second direction X.

In the embodiments of the present disclosure, the first electrode plate of the storage capacitor Cst may be arranged in the semiconductor layer ACT, and the second electrode of the input transistor T1 may be formed by doping in the semiconductor layer ACT. The second electrode of the input transistor T1 and the first electrode plate of the storage capacitor Cst may be formed as an integrated structure.

Optionally, the first electrode plate of the storage capacitor Cst is electrically connected to the fifth gate electrode G5 of the driving transistor T5 through a first transfer portion Z1 located in the first conductive layer SD1.

In some specific embodiments, the second electrode plate of the storage capacitor Cst is located in the second gate layer GT2. A groove C1 is provided on the second electrode plate of the storage capacitor Cst, and the groove C1 exposes the first electrode plate of the storage capacitor Cst. An orthographic projection of the groove C1 on the base substrate 100 overlaps at least partially with an orthographic projection of the first transfer portion Z1 on the base substrate 100. Therefore, the first transfer portion Z1 may be electrically connected to the first electrode plate of the storage capacitor Cst through the groove C1.

In some specific embodiments, the display substrate further includes a first pixel defining layer PDL1 and a second pixel defining layer PDL2 sequentially arranged in a direction away from the base substrate 100. The first pixel defining layer PDL1 is located on a side of the first electrode layer N away from the base substrate 100. The first pixel defining layer PDL1 includes a first pixel opening D11 extending in the first direction Y and a plurality of first defining portions D12 located on two sides of the first pixel opening D11 in the second direction X. The second pixel defining layer PDL2 includes a second pixel opening D21 extending in the second direction X and a plurality of second defining portions D22 located on two sides of the second pixel opening D21 in the first direction Y. In a thickness direction of the display substrate, the first pixel opening D11 overlaps at least partially with the second pixel opening D21 so as to define a third pixel opening D3, and a light emitting portion of at least one light emitting device L is located in the third pixel opening D3. An orthographic projection of at least one constant signal line HL on the base substrate 100 overlaps at least partially with an orthographic projection of at least one first defining portion D12 on the base substrate 100.

The third pixel opening D3 may be a valid light emitting region of the light emitting device L. For example, in an OLED display panel, the light emitting device L of the pixel circuit DE may include a stack of a first electrode, a light emitting layer and a second electrode. The third pixel opening D3 may be a region corresponding to a portion of the light emitting layer sandwiched between the first electrode and the second electrode.

For example, the first defining portion D12 in the first pixel defining layer PDL1 extends in the first direction Y, thereby defining the first pixel opening D11 that extends in the first direction Y. The second defining portion D22 in the second pixel defining layer PDL2 extends in the second direction X, thereby defining the second pixel opening D21 that extends in the second direction X. The first pixel opening D11 intersects with the second pixel opening D21, that is, the two overlap partially in the thickness direction of the display substrate, and a region defined by an edge of an overlapping portion is the third pixel opening D3.

With such structure, when forming a luminescent material by printing, the luminescent material having the same color may flow in the second direction X while being blocked by the second defining portion D22 in the first direction Y. After curing, a luminescent layer for each light emitting device L is formed. A structure such as a groove or a barrier dam may be formed on the first pixel defining layer PDL between two light emitting devices L adjacent in the second direction X, so that the cured luminescent material may form a misalignment at that position, thereby disconnecting the light emitting layers of a plurality of light emitting devices L adjacent in the second direction X.

At least one light emitting device L includes a first electrode N1 located in the first electrode layer N. The first electrode layer N is located between the first pixel defining layer PDL and the second insulation layer J2. The at least one light emitting device L further includes a second electrode located in the second electrode layer (not shown). One of the first electrode N1 and the second electrode may be an anode and the other may be a cathode. For example, the second electrode serves as the cathode and is electrically connected to the second power line VSSL mentioned above to provide a low-level voltage signal. The first defining portion D12 separates the first electrode layer N from the light emitting layer, and the first pixel opening D11 exposes the first electrode N1, so that the light emitting layer located in the first pixel opening D11 may come into contact with the first electrode N1, and then emit light under a driving of electrical signals provided by the first electrode N1 and the second electrode.

Optionally, a distance between two first defining portions D12 adjacent in the second direction X is less than a distance between two first constant signal lines HL adjacent in the second direction X.

In some specific embodiments, an orthographic projection of at least one constant signal line HL on the base substrate 100 is located within an orthographic projection of at least one first defining portion D12 on the base substrate 100. In this way, it is possible to maintain a certain distance between the constant signal line HL and the first pixel opening D11, thereby preventing problems such as a segment difference caused by the constant signal line HL from affecting the uniformity of the first pixel opening D11.

In some specific embodiments, the second pixel opening D21 extends in the second direction X and spans a plurality of pixel circuits DE. At an edge of the second pixel opening D21, two adjacent second defining portions D22 are connected through a third defining portion D23 extending in the first direction Y, so that the second pixel opening D21 forms a closed pattern.

In some specific embodiments, the first power line VDDL, the data line DL, and the reference signal line are located in the same layer and made of the same material. For example, the first power line VDDL, the data line DL and the reference signal line are all located in the second conductive layer SD2, so that layouts of the signal lines on two sides of each pixel circuit DE are consistent, which is conducive to the uniformity of printing the luminescent material.

In some specific embodiments, the display substrate includes a first conductive layer SD1, a first insulation layer J1 and a second conductive layer SD2 sequentially arranged in a direction away from the base substrate 100. The second conductive layer SD2 is located on a side of the first pixel defining layer PDL close to the base substrate 100. At least one pixel circuit DE includes an input transistor T1, and a plurality of data lines DL are located in the second conductive layer SD2. At least one data line DL is electrically connected to the input transistors T1 of two pixel circuits DE adjacent in the second direction X through a first via hole V1 penetrating the first insulation layer J1. An orthographic projection of the first via hole V1 on the base substrate 100 is located within an orthographic projection of at least one first defining portion D12 on the base substrate 100.

It should be noted that herein, the expression “via hole” should be understood as a structure for electrically connecting components in at least two different conductive film layers. For example, a via hole in an insulation film layer exposes at least part of a component in a conductive film layer below the insulation film layer. When a conductive film layer is formed above the insulation film layer, a conductive structure (e.g., conductive plug) may be formed in the via hole in the insulation film layer, and the via hole (including the conductive plug) in the insulation film layer may electrically connect a component in the conductive film layer above the insulation film layer with the component in the conductive film layer below the insulation film layer. In addition, the expression “via hole” may include various forms, including but not limited to through hole, groove, opening, and so on.

In the embodiments of the present disclosure, a separation layer is provided between the first conductive layer SD1 and the semiconductor layer ACT, and the separation layer may include one or more of the first gate (G1) insulation layer GI1, the second gate (G2) insulation layer GI2 and the interlayer dielectric layer ILD. The first insulation layer J1 and the second insulation layer J2 may be single film layers or composite film layers. For example, the first insulation layer J1 may be a composite film layer composed of a plurality of film layers such as a first passivation layer PVX1 and a first planarization layer PLN1, and the second insulation layer J2 may be a composite film layer composed of a plurality of film layers such as a second passivation layer PVX2 and a second planarization layer PLN2. The first electrode of the input transistor T1 may be electrically connected to the first electrode connecting portion Al of the input transistor T1 through a fifth via hole V5 penetrating the separation layer. An orthographic projection of the first via hole V1 on the base substrate and an orthographic projection of the fifth via hole V5 on the base substrate 100 are arranged in the second direction X.

In two pixel circuits DE arranged in the second direction X, the first electrodes of the input transistors T1 are formed as an integrated structure. The orthographic projections of the fifth via holes V5 located in the two pixel circuits DE on the base substrate 100 are respectively located on left and right sides of the orthographic projections of the first via holes V1 on the base substrate 100.

In some specific embodiments, a plurality of first scanning lines GL1 are provided on the display substrate, and the plurality of first scanning lines GL1 include a first gate line GL11 and a second gate line GL12. In two pixel circuits DE adjacent in the second direction X, the first gate electrode G1 of the input transistor T1 of one pixel circuit DE is electrically connected to the first gate line GL11, and the first gate electrode G1 of the input transistor T1 of the other pixel circuit DE is electrically connected to the second gate line GL12, thereby achieving time division multiplexing of the same data line DL.

In the embodiments of the present disclosure, the first gate line GL11 and the second gate line GL12 are arranged in the first direction Y. The first gate line GL11 and the second gate line GL12 are both located in the first conductive layer SD1, and the two are electrically connected to the first gate electrode G1 of the input transistor T1 located in the first gate layer GT1 through a sixth via hole V6 penetrating the separation layer.

In some specific embodiments, an orthographic projection of the sixth via hole V6 on the base substrate 100 and an orthographic projection of the channel portion A13 of the input transistor T1 on the base substrate 100 are arranged in the second direction X.

In some specific embodiments, orthographic projections of the first gate electrodes G1 of the input transistors T1 of two pixel circuits DE adjacent in the second direction X in the second direction X are spaced apart from each other.

In some specific embodiments, at least one pixel circuit DE further includes the light emission control transistor T4. The plurality of constant signal lines HL include a first power line VDDL located in the second conductive layer SD2. The first conductive layer SD1 includes a first power lead VDDS. The first power line VDDL is electrically connected to the first power lead VDDS through a second via hole V2 penetrating the first insulation layer J1, and the light emission control transistors T4 of the plurality of pixel circuits DE arranged in the second direction X are electrically connected to the same first power lead VDDS. An orthographic projection of the second via hole V2 on the base substrate 100 is located within an orthographic projection of at least one first defining portion D12 on the base substrate 100.

In some specific embodiments, the first electrode of the light emission control transistor T4 is located in the first conductive layer SD1. The first electrode of the light emission control transistor T4 and the first power lead VDDS are formed as an integrated structure. The first electrode of the light emission control transistor T4 is electrically connected to the first electrode connecting portion A41 of the light emission control transistor T4 through a seventh via hole V7 penetrating the separation layer.

In some specific embodiments, an orthographic projection of the seventh via hole V7 on the base substrate 100 and an orthographic projection of the second via hole V2 on the base substrate 100 are arranged in the second direction X.

In some specific embodiments, the light emission control line EML is located in the first conductive layer SD1, and is electrically connected to the fourth gate electrode G4 of the light emission control transistor T4 through an eighth via hole V8 penetrating the separation layer.

In some specific embodiments, an orthographic projection of the eighth via hole V8 on the base substrate 100 and the orthographic projection of the second via hole V2 on the base substrate 100 are arranged in the first direction Y.

In the embodiments of the present disclosure, the first conductive layer SD1 includes a plurality of first power leads VDDS arranged in the first direction Y. Each first power line VDDL may be electrically connected to a plurality of first power leads VDDS so as to provide electrical signals for multiple rows and multiple columns of pixel circuits.

Optionally, a second via hole V2 may be provided at an intersection of each first power line VDDL and the first power lead VDDS, so that the first power line VDDL may be electrically connected to the first power lead VDDS through the second via hole V2.

In some specific embodiments, the plurality of constant signal lines HL further include a plurality of reference signal lines. The plurality of reference signal lines include the first reference signal line ViniL located in the second conductive layer SD2. At least one pixel circuit DE further includes the first reset transistor T2. The first conductive layer SD1 includes the lead of the first reference signal line ViniL. The first reference signal line ViniL is electrically connected to the lead of the first reference signal line ViniL through a third via hole V3 penetrating the first insulation layer J1. The first reset transistors T2 of a plurality of pixel circuits DE arranged in the second direction X are electrically connected to the same lead of the first reference signal line ViniL. An orthographic projection of an overlapping portion of at least one first defining portion D12 and at least one second defining portion D22 on the base substrate 100 defines a first pattern, and an orthographic projection of the third via hole V3 on the base substrate 100 is located within the first pattern.

Optionally, the first electrode of the driving transistor T5 is located in the first conductive layer SD1. The first electrode of the driving transistor T5 and a second transfer portion Z2 in the first conductive layer SD1 are formed as an integrated structure. The second electrode connecting portion A2 of the driving transistor T5 is electrically connected to the first electrode of the driving transistor T5 through a ninth via hole V9 penetrating the separation layer, and the second transfer portion Z2 is electrically connected to a fourth transfer portion ZA in the second conductive layer SD2 through a tenth via hole V10 penetrating the first insulation layer J1. The fourth transfer portion ZA is electrically connected to the first electrode N1 of the pixel circuit DE through an eleventh via hole V11 penetrating the second insulation layer J2. The tenth via hole V10 and the eleventh via hole V11 are arranged in the first direction Y.

An orthographic projection of the third via hole V3 on the base substrate 100 and an orthographic projection of the fourth transfer portion Z4 on the base substrate 100 overlap at least partially in the second direction X.

The lead of the first reference signal line ViniL is electrically connected to the first electrode connecting portion A21 of the first reset transistor T2 through a twelfth via hole V12 penetrating the separation layer. The third via hole V3 and the twelfth via hole V12 are arranged in the second direction X.

In some specific embodiments, the second scanning line GL2 is electrically connected to the second gate electrode G2 of the first reset transistor T2 through a thirteenth via hole V13 penetrating the separation layer. An orthographic projection of the thirteenth via hole V13 on the base substrate 100 is located between an orthographic projection of the twelfth via hole V12 on the base substrate 100 and an orthographic projection of the ninth via hole V9 on the base substrate 100.

In some specific embodiments, the first transfer portion Z1 is electrically connected to the first electrode plate of the storage capacitor and the fifth gate electrode G5 of the driving transistor T5 through a fourteenth via hole V14 penetrating the separation layer. An orthographic projection of the fourteenth via hole V14 on the base substrate 100 is located between an orthographic projection of the tenth via hole V10 on the base substrate 100 and the orthographic projection of the eighth via hole V8 on the base substrate 100.

Optionally, the first conductive layer SD1 includes a plurality of leads of the first reference signal line ViniL arranged in the first direction Y. Each first reference signal line ViniL may be electrically connected to a plurality of leads of first reference signal line ViniL so as to provide electrical signals for a plurality of rows and multiple columns of pixel circuits DE.

Optionally, a third via hole V3 is provided at an intersection of each first reference signal line ViniL and each lead of first reference signal line ViniL, so that the first reference signal line ViniL may be electrically connected to the lead of first reference signal line ViniL.

In some specific embodiments, the plurality of reference signal lines further include the second reference signal line VrefL located in the second conductive layer SD2, and at least one pixel circuit DE further includes thed second reset transistor T3. The first conductive layer SD1 includes a lead of second reference signal line VrefL. The second reference signal line VrefL is electrically connected to the lead of second reference signal line VrefL through a fourth via hole V4 penetrating the first insulation layer J1, and the second reset transistors T3 of a plurality of pixel circuits DE arranged in the second direction X are electrically connected to the same lead of second reference signal line VrefL. An orthographic projection of the fourth via hole V4 on the base substrate 100 is located within an orthographic projection of at least one second defining portion D22 on the base substrate 100.

Optionally, the lead of second reference signal line VrefL is electrically connected to the first electrode connecting portion A31 of the second reset transistor T3 through a fifteenth via hole V15 penetrating the separation layer. An orthographic projection of the fourth via hole V4 on the base substrate 100 overlaps at least partially with an orthographic projection of the fifteenth via hole V15 on the base substrate 100.

In some specific embodiments, the third scanning line GL3 is electrically connected to the third gate electrode G3 of the second reset transistor T3 through a sixteenth via hole V16 penetrating the separation layer. An orthographic projection of the sixteenth via hole V16 on the base substrate 100 is located between the orthographic projection of the fifteenth via hole V15 on the base substrate 100 and the orthographic projection of the twelfth via hole V12 on the base substrate 100.

Optionally, the first conductive layer SD1 includes a plurality of leads of second reference signal line VrefL arranged in the first direction Y. Each second reference signal line VrefL may be electrically connected to a plurality of leads of second reference signal line VrefL so as to provide electrical signals for a plurality of rows and multiple columns of pixel circuits DE.

Optionally, a fourth via hole is provided at an intersection of each second reference signal line VrefL and each lead of second reference signal line VrefL, so that the second reference signal line VrefL may be electrically connected to the lead of second reference signal line VrefL.

In some specific embodiments, a plurality of first via holes V1 and a plurality of fourth via holes V4 are provided in the first insulation layer J1, and an orthographic projection of at least one fourth via hole V4 in the first direction X overlaps partially with an orthographic projection of the plurality of first via holes V1 in the second direction X.

In some specific embodiments, the display substrate further includes the first electrode layer N located on a side of the second pixel defining layer PDL2 away from the base substrate 100, and at least one light emitting device L includes the first electrode N1 located in the first electrode layer N. The first electrode N1 of at least one light emitting device L includes a first edge N11 and a second edge N12 opposite to each other in the second direction X. An orthographic projection of one of the first edge N11 and the second edge N12 on the base substrate 100 overlaps at least partially with an orthographic projection of at least one data line DL on the base substrate 100, and an orthographic projection of the other of the first edge N11 and the second edge N12 on the base substrate 100 overlaps at least partially with an orthographic projection of at least one constant signal line HL on the base substrate 100.

For example, the first edge N11 may be a left edge of the first electrode N1, and the second edge N12 may be a right edge of the first electrode N1. In two light emitting devices L adjacent in the second direction X, the first edge N11 of the first electrode N1 of a left light emitting device L overlaps with a data line DL, the second edge N12 of the first electrode N1 of the left light emitting device L overlaps with a constant signal line HL, the first edge N11 of the first electrode N1 of a right light emitting device L overlaps with a constant signal line HL, and the second edge N12 of the first electrode N1 of the right light emitting device L overlaps with a data line DL.

Optionally, the first electrode N1 further includes two edges (such as upper and lower edges) opposite to each other in the first direction Y. The upper edge overlaps at least partially with the lead of first reference signal line ViniL. The lower edge is located below the first electrode of the input transistor T1 and covers the second scanning line for a lower row of pixel circuits DE.

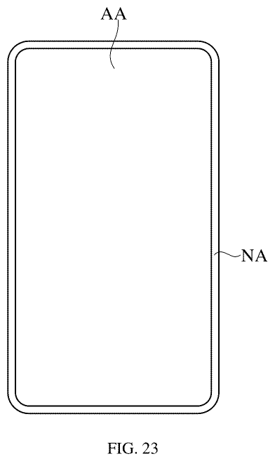

FIG. 22 schematically shows a plan view of a third pixel opening according to the embodiments of the present disclosure.

Referring to FIG. 2A and FIG. 22, in the embodiments of the present disclosure, the first separation regions W1 and the second separation regions W2 in the pixel circuit unit DP are alternately arranged, that is, a data line DL and a constant signal line HL are respectively provided on two sides of each pixel circuit DE. In this example, wiring layouts and via hole layouts are substantially consistent on two sides of the third pixel opening D3 of a plurality of sub-pixels, so that the consistency of the printing environment may be ensured as much as possible. It should be noted that FIG. 22 only shows the edge of the second defining portion D22 in the second pixel defining layer PDL, and a region enclosed by that edge is the second pixel opening D21.

At least some embodiments of the present disclosure further provide a display panel. FIG. 23 schematically shows a schematic diagram of a display panel according to the embodiments of the present disclosure. Referring to FIG. 23, the display panel includes the above-mentioned display substrate. The display panel has a display region, a peripheral region, and related structures therein. For example, the display panel may be a liquid crystal display panel or an OLED display panel.

It should be understood that the display panel according to the embodiments of the present disclosure has all features and advantages of the above-mentioned display substrate. The details may be referred to the above descriptions and will not be repeated here.

At least some embodiments of the present disclosure further provide a display device. The display device may include any apparatus or product having a display function. For example, the display device may be a smart phone, a mobile phone, an e-book reader, a desktop personal computer (PC), a laptop PC, a netbook PC, a personal digital assistant (PDA), a portable multimedia player (PMP), a digital audio player, a mobile medical apparatus, a camera, a wearable apparatus (such as a head-mounted apparatus, electronic clothing, electronic bracelet, electronic necklace, electronic accessory, electronic tattoo, or smart watch), a television, etc.

It should be understood that the display device according to the embodiments of the present disclosure has all features and advantages of the above-mentioned display substrate. The details may be referred to the above descriptions and will not be repeated here.

Although some embodiments of the general technical concept of the present disclosure have been illustrated and explained, those ordinary skilled in the art may understand that changes may be made to those embodiments without departing from the principle and spirit of the general technical concept. The scope of the present disclosure is defined by the claims and their equivalents.

1. A display substrate, comprising:
a base substrate;
a pixel circuit unit provided on the base substrate, wherein the pixel circuit unit comprises a plurality of pixel circuit groups arranged in a first direction, and at least one pixel circuit group comprises a plurality of pixel circuits and a plurality of separation regions;
a plurality of light emitting devices provided on the base substrate and electrically connected to the plurality of pixel circuits, wherein at least one pixel circuit is electrically connected to at least one light emitting device, different pixel circuits are electrically connected to different light emitting devices, the pixel circuits in a same pixel circuit group are electrically connected to light emitting devices having the same color, and the pixel circuits in different pixel circuit groups are electrically connected to light emitting devices having different colors; and
a plurality of data lines and a plurality of constant signal lines provided on the base substrate and electrically connected to the plurality of pixel circuits, wherein the plurality of data lines and the plurality of constant signal lines extend in the first direction,
wherein the plurality of pixel circuits and the plurality of separation regions in a same pixel circuit group are alternately arranged in a second direction intersecting with the first direction;
the plurality of separation regions comprise a plurality of first separation regions and a plurality of second separation regions, and the plurality of first separation regions and the plurality of second separation region are alternately arranged in the second direction; and
the plurality of data lines are located in the plurality of first separation regions, different data lines are located in different first separation regions, two pixel circuits adjacent in the second direction share a same data line, the plurality of constant signal lines are located in the plurality of second separation regions, different constant signal lines are located in different second separation regions, and the plurality of pixel circuits in the pixel circuit unit share the plurality of constant signal lines.

2. The display substrate according to claim 1, wherein the plurality of constant signal lines comprise at least one first power line and a plurality of reference signal lines, and a distance between at least one reference signal line and the first power line adjacent to the at least one reference signal line is substantially the same as a distance between two adjacent data lines.

3. The display substrate according to claim 2, wherein the at least one first power line comprises a plurality of first power lines, and a distance between two adjacent first power lines is substantially the same as the distance between two adjacent data lines.

4. The display substrate according to claim 1, wherein a distance between two adjacent constant signal lines is greater than a distance between two adjacent data lines.

5. The display substrate according to claim 4, wherein the plurality of constant signal lines comprise at least one first power line and a plurality of reference signal lines, and at least one reference signal line is located between two adjacent first power lines.

6. The display substrate according to claim 4, wherein the plurality of constant signal lines comprise at least one first power line and a plurality of reference signal lines, and the plurality of reference signal lines are located on a same side of the at least one first power line.

7. The display substrate according to claim 1, wherein
the plurality of reference signal lines comprise at least one first reference signal line and at least one second reference signal line;
the plurality of light emitting devices are arranged in an array in the first direction and the second direction, the light emitting devices arranged in the second direction have the same color, and the light emitting devices arranged in the first direction have different colors;
the plurality of light emitting devices arranged in the second direction comprise a plurality of light emitting device groups arranged in the second direction, at least one light emitting device group comprises a plurality of light emitting devices, different light emitting device groups comprise different light emitting devices, at least one light emitting device group is configured to display at least one disparity map group, and different light emitting device groups are configured to display different disparity map groups; and
a distance between at least one first reference signal line and a second reference signal line adjacent to the at least one first reference signal line is greater than a size of the light emitting device group in the second direction.

8. The display substrate according to claim 7, wherein the plurality of pixel circuits in the at least one pixel circuit group are electrically connected to the light emitting devices in the plurality of light emitting device groups.

9. The display substrate according to claim 7, wherein
the first reference signal line is electrically connected to first electrodes of the plurality of light emitting devices; and
the display substrate comprises a plurality of pixel circuit units, the first reference signal lines in two adjacent pixel circuit units are insulated and disconnected, and the second reference signal lines in the two adjacent pixel circuit units are communicated.

10. The display substrate according to claim 1, wherein the plurality of second separation regions comprise a plurality of first sub-regions and at least one second sub-region arranged in the second direction, the plurality of constant signal lines are located in the plurality of first sub-regions, a filling structure is provided in the at least one second sub-region, and the filling structure has a thickness substantially the same as a thickness of the constant signal line.

11. The display substrate according to claim 1, wherein
the display substrate further comprises a first pixel defining layer provided on the base substrate and a second pixel defining layer provided on a side of the first pixel defining layer away from the base substrate;
the first pixel defining layer comprises a first pixel opening extending in the first direction and a plurality of first defining portions located on two sides of the first pixel opening in the second direction, the second pixel defining layer comprises a second pixel opening extending in the second direction and a plurality of second defining portions located on two sides of the second pixel opening in the first direction; the first pixel opening overlaps at least partially with the second pixel opening in a thickness direction of the display substrate so as to define a third pixel opening, and at least one light emitting device comprises a light emitting portion located in the third pixel opening; and
an orthographic projection of at least one constant signal line on the base substrate overlaps at least partially with an orthographic projection of at least one first defining portion on the base substrate.

12. The display substrate according to claim 11, wherein the orthographic projection of the at least one constant signal line on the base substrate is located within the orthographic projection of the at least one first defining portion on the base substrate.

13. The display substrate according to claim 11, wherein the display substrate further comprises:
a first conductive layer, a first insulation layer and a second conductive layer sequentially arranged in a direction away from the base substrate, wherein the second conductive layer is located on a side of the first pixel defining layer close to the base substrate;
wherein:
at least one pixel circuit comprises an input transistor, and the plurality of data lines are located in the second conductive layer;
at least one data line is electrically connected to the input transistors of two pixel circuits adjacent in the second direction, through a first via hole penetrating the first insulation layer; and
an orthographic projection of the first via hole on the base substrate is located within the orthographic projection of the at least one first defining portion on the base substrate.

14. The display substrate according to claim 13, wherein
the at least one pixel circuit further comprises a light emission control transistor;
the plurality of constant signal lines comprise a first power line located in the second conductive layer;
the first conductive layer comprises a first power lead;
the first power line is electrically connected to the first power lead through a second via hole penetrating the first insulation layer, and the light emission control transistors of the plurality of pixel circuits arranged in the second direction are electrically connected to a same first power lead; and
an orthographic projection of the second via hole on the base substrate is located within the orthographic projection of the at least one first defining portion on the base substrate.

15. The display substrate according to claim 13, wherein
the plurality of constant signal lines further comprise a plurality of reference signal lines, the plurality of reference signal lines comprise a first reference signal line located in the second conductive layer, and the at least one pixel circuit further comprises a first reset transistor;
the first conductive layer comprises a first reference signal line lead;
the first reference signal line is electrically connected to the first reference signal line lead through a third via hole penetrating the first insulation layer, and the first reset transistors of the plurality of pixel circuits arranged in the second direction are electrically connected to a same first reference signal line lead; and
an orthographic projection of an overlapping portion of at least one first defining portion and at least one second defining portion on the base substrate defines a first pattern, and an orthographic projection of the third via hole on the base substrate is located within the first pattern.

16. The display substrate according to claim 15, wherein
the plurality of reference signal lines further comprise a second reference signal line located in the second conductive layer, and the at least one pixel circuit further comprises a second reset transistor;
the first conductive layer comprises a second reference signal line lead;
the second reference signal line is electrically connected to the second reference signal line lead through a fourth via hole penetrating the first insulation layer, and the second reset transistors of the plurality of pixel circuits arranged in the second direction are electrically connected to a same second reference signal line lead; and
an orthographic projection of the fourth via hole on the base substrate is located within an orthographic projection of the at least one second defining portion on the base substrate.

17. The display substrate according to claim 16, wherein the first insulation layer is provided with a plurality of first via holes and a plurality of fourth via holes, and an orthographic projection of at least one fourth via hole in the second direction overlaps partially with an orthographic projection of the plurality of first via holes in the second direction.

18. The display substrate according to claim 11, wherein
the display substrate further comprises a first electrode layer provided on a side of the second pixel defining layer away from the base substrate, and at least one light emitting device comprises a first electrode located in the first electrode layer; and
the first electrode of the at least one light emitting device comprises a first edge and a second edge opposite to each other in the second direction, an orthographic projection of one of the first edge and the second edge on the base substrate overlaps at least partially with an orthographic projection of at least one data line on the base substrate, and an orthographic projection of the other of the first edge and the second edge on the base substrate overlaps at least partially with the orthographic projection of at least one constant signal line on the base substrate.

19. A display panel, comprising the display substrate according to claim 1.

20. A display device, comprising the display panel according to claim 19.
